(19) United States
(12) Patent Application Publication
(10) Pub. No.: US 2007/0063708 A1
(43) Pub. Date: Mar. 22, 2007

(54) Rectifier open diode detection

(75) Inventor: Donal E. Baker, Rockford, IL (US)

Correspondence Address: CARLSON, GASKEY & OLDS, P.C., 400 WEST MAPLE ROAD, SUITE 350, BIRMINGHAM, MI, 48009, US

(73) Assignee: Hamilton Sundstrand Corporation

(21) Appl. No.: 11/230,829

(22) Filed: Sep. 20, 2005

(51) Int. Cl. G01R 31/08

(52) U.S. Cl. 324/512

(57) ABSTRACT

An open diode detection circuit for use with an auto-transformer rectifier unit includes a plurality of first diodes each connecting one of a plurality of transformer nodes to a detector rail. A comparator compares the detector rail to a rectifier rail, which is also connected by a plurality of diodes to the plurality of transformer nodes. If one of the diodes in the rectifier circuit fails, the voltage on the rail in the rectifier circuit will differ from the voltage on the rail in the detection circuit. This difference will exceed a threshold that is detected by a comparator, which then generates an indication that a diode has failed.

### BACKGROUND OF THE INVENTION

This invention relates to auto-transformer rectifier units and more particularly to a circuit for detecting a failed diode in a rectifier.

In some power system architectures, including aircraft applications, rectifier circuits are used to convert AC power to DC power. These power system architectures may also include a transformer, in which case the combined unit is referred to as a transformer rectifier unit. If the transformer is a non-isolating type, then it is called an auto-transformer rectifier unit (ATRU).

One known ATRU applies a three-phase AC input to a transformer circuit. Nine nodes on the transformer are each connected to a high or positive rail by a diode and to a low or negative rail by another diode in the rectifier circuit. If one of these diodes fails (i.e. provides an open circuit), then the DC power provided will be degraded. It is desirable to detect the failure of any of the diodes in the rectifier circuit.

### SUMMARY OF THE INVENTION

The present invention provides a circuit for detecting an open diode in a rectifier of the type described above, particularly a rectifier incorporated into an auto-transformer rectifier unit of the type described above. The open diode detection circuit includes a plurality of first diodes each connecting one of the nodes of the transformer (i.e., one of the inputs to the rectifier) to a high rail in the detection circuit. Each of the nodes is also connected to a low rail in the detection circuit by another diode. The high rail of the detector circuit is then compared to the high rail of the rectifier circuit while the low rail of the detector circuit is compared to the low rail of the rectifier circuit. One comparator compares the high rails and generates a signal if the high rails differ by a certain margin, while another comparator compares the low rails and generates a signal if they differ by more than a certain margin.

In operation, if one of the high diodes fails (open), the high rail in the rectifier circuit will be lower than the high rail in the detection circuit. The comparator will detect that the difference between the high rails exceeds the threshold and generate a signal indicating the failure of a diode in the rectifier circuit.

Similarly, if one of the low diodes in the rectifier circuit fails (open), the low rail will have a voltage that is not as negative as the low rail of the detection circuit. The comparator will detect that the difference in voltage exceeds the threshold and generate an indication that a diode has failed.

### BRIEF DESCRIPTION OF THE DRAWINGS

Other advantages of the present invention can be understood by reference to the following detailed description when considered in connection with the accompanying drawings wherein:

FIG. 1 is a schematic illustrating the open diode detection circuit according to one embodiment of the present invention in use with an auto-transformer rectifier unit.

### DETAILED DESCRIPTION OF THE PREFERRED EMBODIMENTS

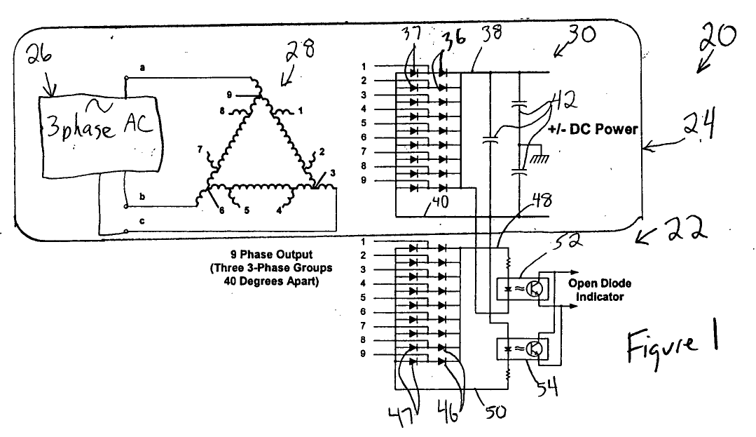

A power system 20 is illustrated in FIG. 1. The power system includes an open diode detector 22 connected to an auto-transformer rectifier unit 24. The auto-transformer rectifier unit 24 provides DC power from an AC input, in this case a three-phase AC power source 26, generating three sine-wave phases. The auto-transformer rectifier unit 24 includes a transformer 28 and a rectifier 30.

The rectifier 30 includes a plurality of first or high diodes 36, each connecting one of the nodes 1-9 of the transformer 28 to a high rail 38 in the rectifier 30. The rectifier 30 also includes a plurality of second or low diodes 37 connecting each of the nodes 1-9 to a low rail 40. Capacitors 32 may further smooth the signal by connecting the high rail 38 to the low rail 40 and by connecting the rails 38, 40 to ground.

The detector 22 includes a plurality of first or high diodes 36 each connecting one of the nodes 1-9 to a high rail 48 in the detector 22. The detector 22 further includes a plurality of second or low diodes 47 each connecting one of the nodes 1-9 to a low rail 50 of the detector 22. It should be noted that while the high diodes 36 and low diodes 37 of the rectifier 30 are large, high current, high power diodes, the high diodes 46 and low diodes 47 of the detector 22 are small, low power, low current diodes.

The detector further includes a first comparator 52 coupled to the high rail 38 of the rectifier 30 and the high rail 48 of the detector 22. The comparator 52 may be an opto-coupler having an LED that flashes based upon any voltage difference between the high rails 38, 48 that exceeds a threshold.

Similarly, a second comparator 54 is coupled between the low rails 40, 50. The second comparator 54 may also include an opto-coupler having an LED which indicates when the voltage difference between the low rails 40, 50 exceeds a threshold. The outputs of the comparators 52, 54 may be OR-ed as shown to simply indicate that any of the diodes, high or low, has failed.

In operation, as each node 1-9 goes high, its associated high diode 36 switches on and supplies high voltage to the high rail 38 of the rectifier 30. When the node 1-9 of the transformer 28 goes low, its associated low diode 37 switches on, thereby pulling the low rail 40 negative.

The detector 22 operates similarly. When any of the nodes 1-9 is high, its associated high diode 46 switches on and drives the high rail 48 high. When any node goes low, its associated low diode 47 switches on, thereby pulling low rail 50 of the detector 22 low.

While the high diodes 36 and low diodes 37 of the rectifier 30 are operational, the high rail 38 of the rectifier 30 will have equal voltage to the high rail 48 to the detector 22. The first comparator 52 will not see a voltage difference exceeding the threshold and will therefore not turn on. Similarly, the voltage on the low rail 40 will substantially equal the low voltage on the low rail 50 of the detector 22, and the second comparator 54 will therefore not see a voltage difference that exceeds the threshold and will therefore not switch on.

In the event that one of the high diodes 36 fails open, the high rail 38 of the rectifier 30 will not be connected to that associated node at that time and will therefore have a voltage that is lower that it would if the high diode 36 had not failed. Since the high rail 48 of the detector 22 will be connected to that same node by a high diode 46 at that time, the first comparator 52 will detect the difference in voltage between the high rail 38 of the rectifier 30 and the high rail 48 of the detector 22 and switch on, thereby giving an indication that a high diode 36 in the rectifier 30 has failed. The first comparator 52 will flash its indicator each time that associated node goes high. Alternatively, the output of the first comparator 52 can be coupled to a latch or capacitor in order to hold its output on in the event of a failure of one of the diodes.

Similarly, if one of the low diodes 37 in the rectifier 30 should fail, the low rail 40 of the rectifier will not be connected to that associated node in the transformer 28. However, since the low rail 50 in the detector 22 will be connected to the node by its associated low diode 37, the low rail 50 in the detector 22 will be pulled low. At that time, the voltages on the low rail 40 in the rectifier 30 and on the low rail 50 of the detector 22 will differ by an amount exceeding the threshold and the second comparator 54 will indicate that a low diode 37 has failed. Again, the output of the second comparator 54 can be latched and/or otherwise held.

Thus, the detector 22 of the present invention provides a simple, inexpensive circuit for detecting a failure of a diode 36, 37 in a rectifier 30. In particular, as illustrated, this detector 22 is particularly useful in the auto-transformer rectifier unit 24.

In accordance with the provisions of the patent statutes and jurisprudence, exemplary configurations described above are considered to represent a preferred embodiment of the invention. However, it should be noted that the invention can be practiced otherwise than as specifically illustrated and described without departing from its spirit or scope. Alphanumeric identifiers in method steps are for ease of reference in dependent claims and do not signify a required sequence unless otherwise indicated in the claim.

1. A power system comprising:
a transformer having a plurality of nodes;
a rectifier having a plurality of first diodes, each connecting one of the plurality of nodes to a rectifier rail;
a detector having a plurality of first diodes each connecting one of the plurality of nodes to a detector rail; and
a comparator comparing a voltage of the rectifier rail to a voltage of the detector rail and generating a signal based upon the comparison.

2. The power system of claim 1 wherein the rectifier rail is a high rectifier rail, the rectifier further including a plurality of second diodes, each connecting the nodes to a low rectifier rail.

3. The power system of claim 2 wherein the detector rail is a high detector rail and wherein the detector further includes a plurality of second diodes, each connecting one of the plurality of nodes to a low detector rail, wherein the comparator is a first comparator, the power system further including a second comparator comparing a voltage of the low rectifier rail to a voltage of the low detector rail and generating a signal based upon the comparison.

4. The power system of claim 3 further including an AC power source connected to the transformer.

5. The power system of claim 4 wherein the AC power source is a 3-phase AC power source.

6. The power system of claim 5 wherein the plurality of nodes includes nine nodes, such that the transformer generates a nine phase output on the nine nodes.

7. The power system of claim 1 wherein the transformer and rectifier comprise an auto transformer rectifier unit.

8. A method for detecting a failed rectifier in an auto transformer rectifier unit having a plurality of phase-separated nodes coupled to a rectifier rail in the rectifier, the method including the steps of:
a) comparing a voltage of the rectifier rail in the auto transformer rectifier unit to a voltage of detector rail, the detector rail coupled to the plurality of nodes by a plurality of first detector diodes; and
b) generating a signal based upon the comparison in said step a).

9. (canceled)

10. (canceled)

11. The method of claim 8 wherein the rectifier rail is a high rectifier rail and the detector rail is a high detector rail, the rectifier further including a low rectifier rail coupled to each of the nodes, the detector further including a low detector rail coupled to each of the nodes by a plurality of second detector diodes, said step a) further including the steps of comparing a voltage of the low detector rail to a voltage of the low rectifier rail and comparing a voltage of the high detector rail to a voltage of the high rectifier rail.

12. The method of claim 8 further including the step of determining whether a difference between the rectifier rail and the detector rail exceeds a threshold.

13. An open diode detector comprising:
a plurality of high diodes each connecting one of a plurality of nodes to a high rail; and
a first comparator comparing voltage of the high rail to a first input and generating a signal based upon the voltage of the high rail differing from the first input by greater than a first threshold.

14. The open diode detector of claim 13 further including:
a plurality of low diodes each connecting one of the plurality of nodes to a low rail; and
a second comparator comparing a voltage of the low rail to a second input and generating a signal based upon the voltage of the low rail differing from the second input by greater than a second threshold.

15. The open diode detector of claim 14 wherein the plurality of high diodes includes nine high diodes, the plurality of low diodes includes nine low diodes, and the plurality of nodes includes nine nodes.
